(19) United States
(12) Patent Application Publication
(10) Pub. No.: US 2011/0084210 A1
(43) Pub. Date: Apr. 14, 2011

(54) Process for producing a particularly strong scintillation material, a crystal obtained by said process and uses thereof

(76) Inventors: Johann-Christoph Von Saldern, Jena (DE); Christoph Seitz, Jena (DE); Frieder Kropfgans, Jena (DE); Jochen Alkemper, Klein-Winternheim (DE); Gunther Wehrhan, Jena (DE); Lutz Parthier, Kleinmachnow (DE)

(21) Appl. No.: 12/899,927

(22) Filed: Oct. 7, 2010

Related U.S. Application Data
(60) Provisional application No. 61/250,188, filed on Oct. 9, 2009.

(30) Foreign Application Priority Data
Oct. 9, 2009 (DE) 10 2009 048 859.6

(51) Int. Cl. G01T 1/20; C30B 15/04; C30B 11/04; C01F 11/20

(52) U.S. Cl. 250/361 R; 117/19; 117/78; 423/497

(57) ABSTRACT

A large-volume scintillation crystal affording a high scintillation yield and having high mechanical strength is obtained by growing a crystal from a melt containing strontium iodide, barium iodide or a mixture thereof and by doping with an activator. To this end, the melt is enclosed in a closed volume. Before and/or during the growing, the melt is in diffusion-permitting connection, via the enclosed volume, with an oxygen getter which sets a constant oxygen potential in the closed volume and the melt. Such a scintillation crystal is suitable for detecting UV-, gamma-, beta-, alpha- and/or positron radiation.

### CROSS-REFERENCE

The invention described and claimed herein below is also described in German Patent Application 10 2009 048 859.6, filed Oct. 9, 2009 in Germany. The aforesaid German Patent Application, whose subject matter is incorporated herein by reference thereto, provides the basis for a claim of priority of invention for the invention claimed herein below under 35 U.S.C. 119 (a)-(d). The invention described and claimed herein below is also described in U.S. Provisional Application Ser. No. 61/250,188, filed on Oct. 9, 2009. The aforesaid German Patent Application, whose subject matter is incorporated herein by reference thereto, provides the basis for a claim of priority of invention for the invention claimed herein below under 35 U.S.C. 119 (e).

### BACKGROUND OF THE INVENTION

1. The Field of the Invention

The invention relates to a process for producing a particularly strong scintillation material, particularly a doped strontium iodide, and also to a crystal obtained by the process and to the uses thereof.

2. The Description of the Related Art

Scintillators are materials which, when exposed to energy-rich radiation, for example gamma-radiation, UV-radiation or also alpha- or beta-radiation, give off the energy introduced in this manner in the form of light, particularly visible light. Scintillators, particularly inorganic crystalline scintillators, are usually doped with a so-called activator which takes up the irradiated energy from the crystalline lattice and releases this energy by giving off a photon, thus returning to its unexcited ground state. Such scintillators are gaining increasing importance in the fields of chemistry, physics, medicine and even geology. For example, they are used in imaging processes, for example positron emission tomography (PET). Typical scintillation materials are, for example, the alkali metal halides and alkaline earth metal halides doped with a rare earth element as activator.

For example, U.S. Pat. No. 3,163,608 describes a luminescent material which consists of an alkaline earth metal halide that comprises the Ba, Ca and Sr cations and is doped with a rare earth, particularly Sm²⁺, Tm²⁺ and U³⁺ in an amount of 10⁻⁶ to 10⁻¹ mole. U.S. Pat. No. 3,373,279 describes a europium-activated strontium iodide scintillation material with a short relaxation time. However it has been found that the energy yield of such scintillation materials can be further improved. For example, N. J. Cherepy, et al., in Applied Physical Letters 92, 083508 (2008), describe scintillators consisting of europium-doped strontium and barium iodide that exhibit a high light yield. To this end, however, the crystal material must first be grown in a vacuum to remove impurities that are volatile in vacuum and then be further purified by means of a zone melting material. At the end, the final, so-called third crystal is obtained by an ultra-purification process. Such materials are usually produced in crystalline form in a simple manner by the usual crystal-growing processes, for example the Bridgman-Stockbarger process or the Czochralski process. It has been shown, however, that all these processes provide crystals of insufficient mechanical strength. Moreover, it has thus far not been possible to produce such materials with a sufficiently large crystal volume.

### SUMMARY OF THE INVENTION

Hence, the object of the invention is to provide a crystalline scintillation material of higher mechanical strength and stability. An additional object of the invention is to produce this material with a large crystal volume.

These objects are attained by the measures defined in the claims.

These objects can be attained with a scintillation material of the general formula:

Sr_{1-x-y}Ba—_{x-z}I₂K_{y+z}:A

wherein x has a value of 1-0, and
y+z has a value of 5×10^{˜}6 to 10^{˜}2,
K stands for one or more monovalent, divalent or trivalent metal cations, and A denotes an activator,
provided that when the crystalline base material used is barium iodide and/or strontium iodide, and
when the crystal is grown in a closed volume, which is connected, or is in communication, with a reducing atmosphere and/or an oxygen getter, particularly a metal and/or halide and/or some other reducing gas system.

It has been found that the size of the crystals achievable according to the prior art is limited both by the strength of the material and by the combination with internal strains produced by the incorporation of oxygen or water of hydration stemming from the impurities present in the raw material. These strains and the strains induced by the temperature gradients during crystal-growing reduce the strength of the material and generate crystal defects, such as dislocations. Such defects lead to non-radiating recombination and thus to a reduced light yield. Moreover, they lead to the fissuring of the grown crystal, which makes it unsuitable for use.

All materials capable of reducing the oxygen content and/or water of hydration to a value of less than 1000 ppm, particularly less than 100 ppm, in the volume around the melt and thus also in the crystal to be grown are suitable as oxygen getters. Typically this content leads to an undesirable residual amount of oxygen or water of less than 10 ppm.

Furthermore it has been found that the objects of the invention can also be attained by adding to the crystal material one or more doping agents with an ionic radius that differs from that of the alkaline earth metal, but only to such an extent that it can still replace the alkaline earth metal in the crystal lattice. For this purpose, according to the invention, it is possible to use either divalent ions or a combination of a monovalent and a trivalent ion provided they replace each other to an extent such that their combination can also replace the alkaline earth ion in the crystal lattice. In principle, two different divalent cations can also be used.

It has been found that other rare earths elements can also be used for this purpose.

The alkaline earth metal ion to be replaced is preferably the strontium ion. Suitable divalent ions are, in particular, Ba, Mg, Ca, Pb, Cd, Zn, Cu or the activator, for example Eu. Suitable monovalent ions are, in particular, K, Li and Na.

Trivalent ions preferred according to the invention are Ga, In and Al. Preferred combinations of monovalent and trivlanet ions are, in particular Ga—K and In—Na.

A reducing atmosphere used in the process of the invention comprises, for example, HI, H₂ and/or CO, CO₂. The partial pressure of the reducing component is preferably less than 500 mbar, particularly less than 100 mbar, with less than 50 mbar being particularly preferred. Such an atmosphere can be obtained, for example, with the aid of a closed container, for example an ampoule, which communicates, that is to say is connected, with the closed crystal-growing apparatus.

In an alternative embodiment of the invention, for example in a half-open apparatus or in a vacuum-tight, closed container, oxygen getters are used additionally or alternatively to remove the oxygen or water. For this purpose it is possible to use any material capable of reducing the oxygen content in the volume surrounding the melt to the desired values and particularly the aforesaid ones.

Suitable oxygen getters are metals or the oxides thereof. Preferred metals or oxides thereof are nickel, titanium and copper. Other suitable oxygen getters are fluorine, chlorine and bromine, of which fluorine and/or chlorine are particularly preferred.

If such gaseous oxygen getters are used, they are preferably present in an amount corresponding to the aforesaid partial pressures for the reducing atmosphere.

It has also been found that the aforesaid objects can be attained by replacing part of the strontium in the crystal lattice by a dopant consisting of a cation, which can be incorporated into the crystal without any problems and which has an ionic radius different from that of the strontium. In a preferred embodiment, at least two different cations are used, one of which having an ionic radius greater than that of the strontium and the other having an ionic radius that is at least smaller than that of the strontium. The cations substituting the strontium as dopants can be monovalent as well as divalent or trivalent cations. It is preferred to use, in particular, a mixture of monovalent and trivalent cations that has a neutral charge or a mixture of divalent cations, of which one has a greater ionic radius and the other a smaller ionic radius than that of strontium.

Surprisingly, the inventors have found that by the addition of the aforesaid co-doping it is possible to achieve higher heat conductivity of the melt and particularly of the crystal. In this manner, it is possible to achieve a particularly low temperature gradient in the solid material and thus only slight dislocation movements. In addition, the geometry of the phase boundary can be directly influenced as a result of the increased heat outflow. They have also found that in this manner the scintillation properties can be improved and the formation of energy levels in the band gap that can be occupied can be prevented.

In an embodiment preferred according to the invention, the strength, and particularly the fracture resistance, of the scintillation material can be achieved by the addition of at least one alkali metal and/or at least one element from the third main group. The concentrations here are always in the range between 5 ppm and 10,000 ppm, preferably between 5 ppm and 1,000 ppm and most preferably between 10 ppm and 100 ppm. This is also achieved by adding to the crystalline material other divalent ions comprising at least one ion, the ionic radius of which is smaller than that of the strontium, and another ion, the ionic radius of which is greater than that of the strontium. It is preferred in this case that the added ions have a smaller ionic radius than that of the strontium and it is particularly preferred if several ions are added that have a smaller and a larger ionic radius than that of the strontium. The concentrations of these dopants are also in the range between 5 ppm and 10,000 ppm, preferably between 5 ppm and 1,000 ppm and most preferably between 10 ppm and 100 ppm.

According to the invention, several possible scintillation activators can be used. Preferred, however, are activators from the rare earth group. The term “rare earths” includes, in particular, La, Ce, Pr, Nd, Pm, Sm, Eu, Gd, Tb, Dy, Ho, Er, Tm, Yb, Lu as well as Y and Sc.

The rare earths preferred according to the invention comprise praseodymium, cerium and europium. It has been found that, when these activators are used, particularly europium, the use of oxygen getters according to the invention, particularly the use of a reducing atmosphere, substantially improves the light yield during scintillation.

According to the invention, it has been found that, when europium is used, the light yield can be further improved if in the crystal the charge neutrality is violated by the addition of an excess of the trivalent ion. This excess is preferably at the most 10 ppm, a maximum of 5 ppm being preferred. Particularly preferred is a maximum excess of the trivalent ion of 1 ppm. The trivalent ions used in this case are particularly those trivalent ions, which are added to the crystal as dopants.

Such crystals can be produced by the usual processes. Particularly preferred is crystal-growing directly from the melt, for example by the Czochralski process or the Bridgman process. Another possibility consists, for example, of using the VGF (vertical gradient-freeze) process. The growing process can be carried out in all crucible materials known to be suitable for this purpose, for example glass, carbon, tantalum, iridium or platinum.

The crystals according to the invention can be monocrystalline or polycrystalline. According to another embodiment of the invention, scintillation ceramics can be made from such crystals in a known manner.

The crystals produced according to the invention are particularly well suited for the detection of UV-, gamma-, beta-, alpha- and/or positron radiation. For this reason, they find widespread use in medical technology, for example in PET, SPECT and the like, as well as in mineral oil and natural gas raw material searching and in the detection of ionizing radiation.

### EXAMPLES

The following examples provide a more detailed explanation of the process of the invention.

### Example 1

### Preparation of a Ceramic Strontium Iodide Scintillator

Strontium iodide is mixed with ammonium iodide in a 1:3 ratio and then melted. As a result, the ammonium iodide decomposes into ammonia and hydrogen iodide. The residual impurities consisting of H₂O in the SrI₂ are removed by the liberated hydrogen iodide. Further purification of the crystalline powder can be accomplished by vacuum distillation. The powder thus obtained has a particle size of 50-200 nm. In a first step, the powder is compressed isostatically at 1 kbar at room temperature to give a green body and then hot-isostatically at a temperature of 10 K below the melting point at 1.5 kbar under vacuum. After a holding time of 5-120 minutes, the pressed article is cooled to 200-300° C. at a rate of at least 5 K/min. In this manner, a visually transparent ceramic scintillation material is obtained.

### Example 2

### Preparation of a Crystalline Strontium Iodide Scintillator

In an Ar-filled glove box (H₂O and O₂ contents less than 5 ppm each), 500 g of SrI₂ and 18 g of EuI₂ are weighed into a quartz ampoule having an internal diameter of 30 mm. The ampoule is then evacuated, filled with Ar to 50 mbar and sealed. A 30-mm-long capillary having an internal diameter of 3 mm is positioned at the tip of the ampoule. The ampoule is placed into a 3-zone Bridgman furnace. At first, the temperature is held at 640° C. for 48 hours. Then, a crystal is grown at a withdrawal rate of 0.8 mm/h. The ampoule is opened in a glove box, and the crystal is removed.

While the invention has been illustrated and described as embodied in a process for producing a particularly strong scintillation material, a crystal obtained by the process and uses thereof, it is not intended to be limited to the details shown, since various modifications and changes may be made without departing in any way from the spirit of the present invention.

Without further analysis, the foregoing will so fully reveal the gist of the present invention that others can, by applying current knowledge, readily adapt it for various applications without omitting features that, from the standpoint of prior art, fairly constitute essential characteristics of the generic or specific aspects of this invention.

What is claimed is new and is set forth in the following appended claims.

We claim:

1. A process of producing large-volume scintillation crystals affording a high scintillation yield and having high mechanical strength, said process comprising the steps of:
a) growing a crystal from a melt in a closed volume enclosing the melt and doping with an activator, said melt containing strontium iodide, barium iodide or a mixture thereof; and
b) before and/or during the growing of the crystal, the melt is in a diffusion-permitting connection, via the closed volume, with an oxygen getter, the oxygen getter setting a constant oxygen potential in the closed volume and the melt.

2. The process according to claim 1, wherein the oxygen getter is a metal/metal oxide.

3. The process according to claim 1, wherein the oxygen getter is at least one member selected from the group consisting of nickel/nickel oxide, titanium/titanium dioxide, copper/copper oxide, fluorine/fluorine oxide, chlorine/chlorine oxide and CO/CO₂.

4. The process according to claim 1, wherein the activator is a rare earth element.

5. The process according to claim 1, wherein the doping with the activator comprises partly replacing strontium and/or barium with another cation.

6. The process according to claim 5, wherein said another cation has an ionic radius that is greater or smaller than that of said strontium.

7. The process according to claim 5, wherein the strontium and/or barium is in part replaced by at least two different cations, one of which has an ionic radius that is smaller than that of the strontium and/or barium and the other of which has an ionic radius that is greater than that of the strontium and/or barium.

8. The process according to claim 5, wherein part of the strontium and/or barium is replaced by a mixture of monovalent and trivalent cations.

9. A scintillation crystal obtained by the process according to claim 1.

10. A detection device for detecting gamma-, beta-, alpha- and/or positron radiation, said detection device comprising a scintillation crystal obtainable by the process according to claim 1.
